(19) United States
(12) Patent Application Publication
(10) Pub. No.: US 2025/0377602 A1
(43) Pub. Date: Dec. 11, 2025

(54) PATTERN INSPECTION APPARATUS AND PATTERN INSPECTION METHOD

(71) Applicant: NuFlare Technology, Inc., Yokohama-shi (JP)

(72) Inventors: Toshiaki OTAKI, Yokohama-shi (JP); Ryoichi HIRANO, Setagaya-ku (JP)

(73) Assignee: NuFlare Technology, Inc., Yokohama-shi (JP)

(21) Appl. No.: 19/226,371

(22) Filed: Jun. 3, 2025

(30) Foreign Application Priority Data
Jun. 6, 2024 (JP) 2024-091918

(51) Int. Cl. G03F 7/00; G01N 21/956; G02B 27/30; G03F 1/84; G06T 7/00

(52) U.S. Cl. CPC G03F 7/706845; G01N 21/95607; G02B 27/30; G03F 7/7065; G03F 7/706849; G06T 7/001; G03F 1/84; G06T 2207/30148

(57) ABSTRACT

According to one aspect of the present invention, a pattern inspection apparatus includes a height adjustment mechanism configured to adjust a height position of a pattern forming surface of the target object to a focus height position of the inspection light by using a height position deviation amount distribution which is acquired based on applying the measuring light to the target object and indicates a deviation amount of the pattern forming surface of the target object deviated from the focus height position, wherein in a case of scanning a k-th (k being an integer of at least 1) stripe region with the inspection light, an irradiation position of the inspection light on the target object and an irradiation position of the measuring light on the target object are set such that a (k+m)th (m being an integer of at least 1) stripe region is scanned with the measuring light.

### CROSS-REFERENCE TO RELATED APPLICATION

This application is based upon and claims the benefit of priority from prior Japanese Patent Application No. 2024-091918 filed on Jun. 6, 2024 in Japan, the entire contents of which are incorporated herein by reference.

### BACKGROUND OF THE INVENTION

### Field of the Invention

Embodiments of the present invention relate to a pattern inspection apparatus and a pattern inspection method. For example, they relate to an apparatus that inspects pattern defects of an exposure mask used in semiconductor manufacturing, and to a method for adjusting a focus position of that apparatus.

### Description of Related Art

With recent progress in high integration and large capacity of the LSI (Large Scale Integrated circuits), the line width (critical dimension) necessary for circuits of semiconductor elements is further decreasing. Such semiconductor elements are manufactured through circuit forming processing by exposing and transferring a pattern onto a wafer by means of a reduced projection exposure apparatus known as a stepper, using an original or “master” pattern (also called a mask or a reticle, hereinafter generically referred to as a mask) on which a circuit pattern has been formed.

Since LSI manufacturing needs an enormous production cost, it is essential to improve the yield. One of major factors that decrease the yield is due to pattern defects on a mask for exposing/transferring an ultrafine pattern onto a semiconductor wafer by the photolithography technology. In recent years, with miniaturization of dimensions of LSI patterns formed on a semiconductor wafer, dimensions to be detected as a pattern defect have become extremely small. Therefore, a pattern inspection apparatus for inspecting defects of a transfer mask used in manufacturing LSI needs to be highly accurate.

As an inspection method, for example, there is “die-to-die inspection” or “die-to-database inspection”. The “die-to-die inspection” method compares data of optical images of identical patterns at different positions on the same mask. The “die-to-database inspection” method inputs, into an inspection apparatus, writing data (design data) generated by converting pattern-designed CAD data to a writing-apparatus-specific format to be input to the writing apparatus when a pattern is written on the mask, generates a reference image based on the input writing data, and compares the generated reference image with an optical image being measured target data obtained by imaging the pattern.

In such an inspection apparatus, what is needed is to clearly obtain pattern images on the mask to be inspected. However, since a finite focal depth exists in the optical system of the inspection apparatus, the inspection surface of an inspection target needs to be continuously maintained within the focal depth of the optical system during the inspection. In other words, the contrast of an acquired image needs to be maintained within an allowable range. Since continuous imaging by scanning the mask while moving the stage is needed in the inspection apparatus, it is not realistic to adjust a focus of the optical system by calculating the image contrast one by one during the inspection because it causes a shortage of the processing time.

Then, the inspection apparatus employs, in addition to the inspection optical system for acquiring images, an autofocus mechanism that detects a height-wise displacement of an inspection target object against the inspection optical system in order to adjust the height position.

Currently, shortening of the inspection light wavelength is progressing with recent miniaturization of patterns. Along with this, the focal depth of the inspection optical system has become shallow/short. Accordingly, although conventionally the accuracy of the measuring system of the autofocus mechanism installed independently close to the inspection optical system has been sufficient, it recently becomes difficult to perform a highly accurate focus adjustment because various change factors (dependency on temperature/mechanical transformation) of the inspection optical system cannot be detected if not conducting (in-situ) measurement which uses the inspection optical system itself. Thus, there is employed a configuration in which the inspection optical system is partially utilized as an autofocus mechanism (e.g., refer to Japanese Patent Application Laid-open (JP-A) No. 2020-125941).

In the autofocus mechanism, an autofocus image is projected ahead in a scanning direction in the inspection field of view of a transmission inspection and/or a reflection inspection, and an autofocus signal showing a focus deviation of the autofocus image is fed back to adjust the stage height in order to make the autofocus image focused. However, even if the autofocus signal can be fed back at a high speed, a timing occurs when the stage movement delays in following the autofocus signal, and therefore, the inspection field of view is not focused. If a pattern is imaged at the timing when the stage movement cannot follow the autofocus signal, the image becomes blur, which causes a problem that the blur is misidentified as a defect, or omission occurs in defect detection.

### BRIEF SUMMARY OF THE INVENTION

According to one aspect of the present invention, a pattern inspection apparatus includes
a light source configured to emit a first light,
a stage configured to be movable and to mount thereon a target object on which a pattern is formed,
a slit plate, in which an opening is formed, configured to restrict a passage of a measuring light which is a portion of the first light emitted from the light source and is for measuring a deviation amount of the target object from a focus height,
an illumination optical system configured to irradiate the target object with the measuring light having passed through the slit plate,
a stage control circuit configured to control a movement of the stage such that each stripe region of a plurality of stripe regions obtained by dividing an inspection region of the target object by a predetermined width is scanned with an inspection light being another portion of the first light emitted from the light source,
a sensor configured to receive a pattern image of the target object formed by a light, being one of a light transmitted through the target object and a light reflected from the target object, due to scanning with the inspection light,
a comparison circuit configured to compare the pattern image received by the sensor with a predetermined reference image, and
a height adjustment mechanism configured to adjust a height position of a pattern forming surface of the target object to a focus height position of the inspection light by using a height position deviation amount distribution which is acquired based on applying the measuring light to the target object and indicates a deviation amount of the pattern forming surface of the target object deviated from the focus height position, wherein
in a case of scanning a k-th (k being an integer of at least 1) stripe region with the inspection light, an irradiation position of the inspection light on the target object and an irradiation position of the measuring light on the target object are set such that a (k+m)th (m being an integer of at least 1) stripe region is scanned with the 10 measuring light.

According to another aspect of the present invention, a pattern inspection method includes
restricting, using a slit plate in which an opening is formed, a passage of a measuring light which is a portion of a first light emitted from a light source and is for measuring a deviation amount of a target object from a focus height,
irradiating, using an illumination optical system, the target object, on which a pattern is formed and which is placed on a stage, with the measuring light having passed through the slit plate,
scanning each stripe region of a plurality of stripe regions, obtained by dividing an inspection region of the target object by a predetermined width, with an inspection light being another portion of the first light emitted from the light source,
receiving, by a sensor, a pattern image of the target object formed by a light, being one of a light transmitted through the target object and a light reflected from the target object, due to scanning with the inspection light,
comparing the pattern image received by the sensor with a predetermined reference image, and
adjusting a height position of a pattern forming surface of the target object to a focus height position of the inspection light by using a height position deviation amount distribution which is acquired based on applying the measuring light to the target object and indicates a deviation amount of the pattern forming surface of the target object deviated from the focus height position, wherein
in a case of scanning a k-th (k being an integer of at least 1) stripe region with the inspection light, an irradiation position of the inspection light on the target object and an irradiation position of the measuring light on the target object are set such that a (k+m)th (m being an integer of at least 1) stripe region is scanned with the measuring light.

### BRIEF DESCRIPTION OF THE DRAWINGS

FIG. 1 is a configuration diagram showing a pattern inspection apparatus according to a first embodiment;

FIG. 2 is a conceptual diagram illustrating an inspection region according to the first embodiment;

FIG. 3 is an illustration showing an example of each region on the substrate surface according to a comparative example of the first embodiment;

FIG. 4 is an illustration for explaining an example of an autofocusing operation according to a comparative example of the first embodiment;

FIG. 5 is an illustration showing an example of each region on the substrate surface according to the first embodiment;

FIG. 6 is an illustration showing an example of a focusing operation according to the first embodiment;

FIG. 7 is an illustration showing an example of a configuration of an illumination optical system according to the first embodiment;

FIG. 8 is an illustration showing an example of a positional relationship among an inspection field of view, a focus slit image, and an objective lens field of view according to the first embodiment;

FIG. 9 is an illustration showing another example of a positional relationship among an inspection field of view, a focus slit image, and an objective lens field of view according to the first embodiment;

FIG. 10 is an illustration showing another example of a positional relationship among an inspection field of view, a focus slit image, and an objective lens field of view according to the first embodiment;

FIG. 11 is an illustration showing another example of a positional relationship among an inspection field of view, a focus slit image, and an objective lens field of view according to the first embodiment;

FIG. 12 is a block diagram showing an example of an internal configuration of a focus control circuit according to the first embodiment;

FIG. 13 is a flowchart showing an example of main steps of an inspection method according to the first embodiment;

FIG. 14 is an illustration showing an example of a height distribution of the XYθ table 102 (stage) at the 0th (n=0) inspection stripe, and an example of a height position deviation distribution at the first (n=1) inspection stripe according to the first embodiment;

FIG. 15 is an illustration showing an example of a relationship between a focus signal and a stage height position according to the first embodiment;

FIG. 16 is an illustration showing an example of a relationship between a pattern forming surface and a height position distribution based on a focus signal according to the first embodiment;

FIG. 17 is an illustration for explaining a method of calculating a height position deviation distribution of an actual pattern forming surface according to the first embodiment;

FIG. 18 is a diagram illustrating filter processing according to the first embodiment;

FIG. 19 is an example of an internal configuration of a comparison circuit according to the first embodiment;

FIG. 20 is an illustration showing an example of a height distribution of an XYθ table (stage) at the first (n=1) inspection stripe, and an example of a height position deviation distribution at the second (n=2) inspection stripe according to the first embodiment; and

FIG. 21 is an illustration showing an example of a height distribution of the XYθ table (stage) at the second (n=2) inspection stripe, and an example of a height position deviation distribution at the third (n=3) inspection stripe according to the first embodiment.

### DETAILED DESCRIPTION OF THE INVENTION

Embodiments of the present invention provide an inspection apparatus and method that can prevent or reduce a follow-up delay of the stage movement occurring in focusing the inspection field of view.

### First Embodiment

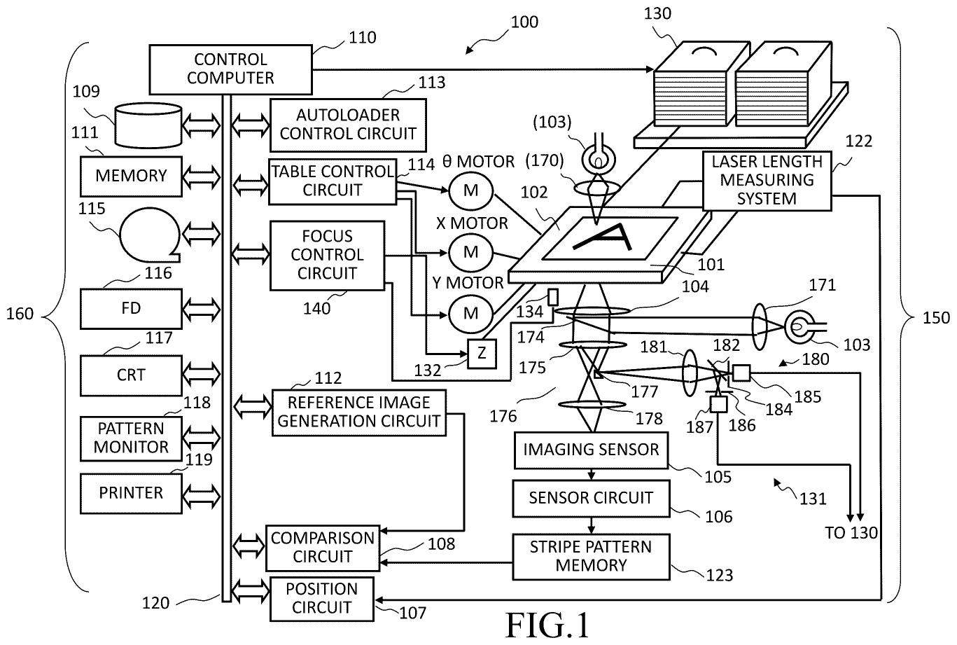

FIG. 1 is a configuration diagram showing a pattern inspection apparatus according to a first embodiment. As shown in FIG. 1, an inspection apparatus 100 that inspects defects of a pattern formed on an inspection target substrate, such as a mask, includes an optical image acquisition mechanism 150 and a control system circuit 160.

The optical image acquisition mechanism 150 includes a light source 103, a reflection illumination optical system 171, an XYθ table 102 movably arranged, a magnifying optical system 104, a beam splitter 174, a first image forming lens 175, a separating mirror 177, an image forming optical system 178, a focusing mechanism 131, an imaging sensor 105, a sensor circuit 106, a stripe pattern memory 123, a laser length measuring system 122, and an autoloader 130. In the case of performing a transmission inspection using a transmitted light, a transmission illumination optical system 170 is further arranged. In the case of performing only a reflection inspection using a reflected light without performing a transmission inspection, the transmission illumination optical system 170 may be omitted. In the case of simultaneously performing a transmission inspection and a reflection inspection, an imaging sensor (not illustrated) is further added to acquire an image for the reflection inspection by the imaging sensor 105 and an image for the transmission inspection by the added imaging sensor.

The focusing mechanism 131 includes a focusing optical system 180, a light amount sensor 185 (first light amount sensor), a light amount sensor 187 (second light amount sensor), a Z drive mechanism 132, and a position sensor 134.

The focusing optical system 180, the light amount sensor 185, and the light amount sensor 187 configure a portion of a confocal sensor.

The focusing optical system 180 includes an image forming optical system 181, a beam splitter 182, slit plates 184, and 186. The focusing optical system 180, when a substrate 101 is irradiated with a measurement light being a portion of a light (the first light) emitted from a light source, leads a light (the second light) transmitted through or reflected from the substrate 101 to the light amount sensors 185 and 187. The beam splitter 182 is placed on the front side of the focus position. The slit plate 184 is arranged at the front focus position, and receives a light transmitted through the beam splitter 182. The light amount sensor 185 measures the amount of light having passed through the slit plate 184 placed at the front focus position. The slit plate 186 is arranged at the back focus position (or “rear focus position”), and receives a light branched by the beam splitter 182. The light amount sensor 187 measures the amount of light having passed through the slit plate 186 placed at the back focus position.

On the XYθ table 102 (an example of a stage), the substrate 101 conveyed from the autoloader 130 is placed. The substrate 101 is, for example, an exposure photomask used for transfer printing a pattern onto a semiconductor substrate such as a wafer. A plurality of figure patterns to be inspected are formed on the photomask. The substrate 101 is disposed, for example, with its pattern forming surface facing downward, on the XYθ table 102. The XYθ table 102 is an example of the stage._

As the imaging sensor 105, a line sensor or a two-dimensional sensor is used. For example, it is preferable to use a TDI (time delay integration) sensor. The TDI sensor includes a plurality of photo sensor elements arranged two-dimensionally. When an image is acquired by each photo sensor element, a predetermined image accumulation time is set. In the TDI sensor, outputs of a plurality of photo sensor elements arrayed in a scanning direction are integrated to be output. The plurality of photo sensor elements arrayed in a scanning direction acquire images of the same pixel while shifting the time according to the movement of the XYθ table 102. In the case of using a line sensor, a plurality of photo sensor elements are arranged in the direction perpendicular to the scanning direction.

In the control system circuit 160, a control computer 110 which controls the whole of the inspection apparatus 100 is connected, through a bus 120, to a position circuit 107, a comparison circuit 108, a reference image generation circuit 112, an autoloader control circuit 113, a table control circuit 114, a focus control circuit 140, a magnetic disk drive 109, a memory 111, a magnetic tape drive 115, a flexible disk drive (FD) 116, a CRT 117, a pattern monitor 118, and a printer 119. The imaging sensor 105 is connected to the stripe pattern memory 123 which is connected to the comparison circuit 108. The reference image generation circuit 112 is also connected to the comparison circuit 108.

The position sensor 134 measures the height position of the backside of the XYθ table 102. When the substrate 101 is placed on the XYθ table 102, the height position of the XYθ table 102 backside to be measured is adjusted to be flush with the reference plane (for example, position without a pattern) of the pattern forming surface of the substrate 101, for example. Therefore, the position sensor 134 can measure the height position of the reference plane of the pattern forming surface of the substrate 101 by measuring the height position of the backside of the XYθ table 102. Alternatively, the position sensor 134 measures the height position of the reference plane of the pattern forming surface of the substrate 101.

Outputs of the position sensor 134 are connected to the focus control circuit 140. Outputs of the light amount sensors 185 and 187 are also connected to the focus control circuit 140.

Each “ . . . circuit”, such as the position circuit 107, the comparison circuit 108, the reference image generation circuit 112, the autoloader control circuit 113, the table control circuit 114, and the focus control circuit 140 includes processing circuitry. The processing circuitry includes, for example, an electric circuit, computer, processor, circuit board, quantum circuit, semiconductor device, or the like. Common processing circuitry (the same processing circuitry), or different processing circuitry (separate processing circuitry) may be used for each “circuit”. For example, each “ . . . circuit”, such as the position circuit 107, the comparison circuit 108, the reference image generation circuit 112, the autoloader control circuit 113, the table control circuit 114, and the focus control circuit 140 may be configured and executed by the control computer 110. Input data necessary for the position circuit 107, the comparison circuit 108, the reference image generation circuit 112, the autoloader control circuit 113, the table control circuit 114, and the focus control circuit 140, and operated (calculated) results are stored in a memory (not shown) in each circuit or the memory 111 each time. Input data necessary for the control computer 110 and operated (calculated) results are stored in a memory (not shown) in the control computer 110, or the memory 111 each time. A program for causing a computer or a processor to execute processing and the like may be stored in a recording medium, such as the magnetic disk drive 109, the magnetic tape drive 115, the FD 116, the ROM (Read Only Memory), or the like.

In the inspection apparatus 100, a reflection inspection optical system and/or a transmission inspection optical system are installed as an inspection optical system 176. The reflection inspection optical system of high magnification is configured by the light source 103, the reflection illumination optical system 171, the beam splitter 174, the magnifying optical system 104, the XYθ table 102, and the image forming optical system 178. The transmission inspection optical system of high magnification is configured by the light source 103, the transmission illumination optical system 170, the XYθ table 102, the magnifying optical system 104, and the image forming optical system 178.

The XYθ table 102 is driven by the table control circuit 114 under the control of the control computer 110. The XYθ table 102 can be moved by a drive system such as a three-axis (X, Y, θ) motor which drives the table in the directions of X, Y, and 0. For example, a step motor can be used as each of these X, Y, and 0 motors. The XYθ table 102 is movable in the horizontal direction and the rotation direction by the X-, Y-, and θ-axis motors. The XYθ table 102 is an example of the stage. The movement position of the substrate 101 placed on the XYθ table 102 is measured by the laser length measuring system 122, and supplied to the position circuit 107. The transfer processing of the substrate 101 from the autoloader 130 to the XYθ table 102, and from the XYθ table 102 to the autoloader 130 is controlled by the autoloader control circuit 113.

The XYθ table 102 is driven in the Z direction by the Z drive mechanism 132 controlled by the focus control circuit 140. As the Z drive mechanism 132, it is preferable to use a piezoelectric element or a step motor, for example. The height position of the XYθ table 102 is measured by the position sensor 134, and the measurement result is output to the focus control circuit 140.

Writing data (design data) used as a basis for forming patterns on the substrate 101 which is to be inspected is input from the outside of the inspection apparatus 100, and stored in the magnetic disk drive 109. The writing data defines a plurality of types of figure patterns, and each figure pattern is usually configured by combining a plurality of element figures. It is acceptable to configure a figure pattern by one figure. Then, each pattern corresponding to and based on each figure pattern defined by the writing data is formed on the inspection substrate 101.

FIG. 1 is an illustration showing configuration elements necessary for describing the first embodiment. Needless to say, other configuration elements generally necessary for the inspection apparatus 100 may also be included therein.

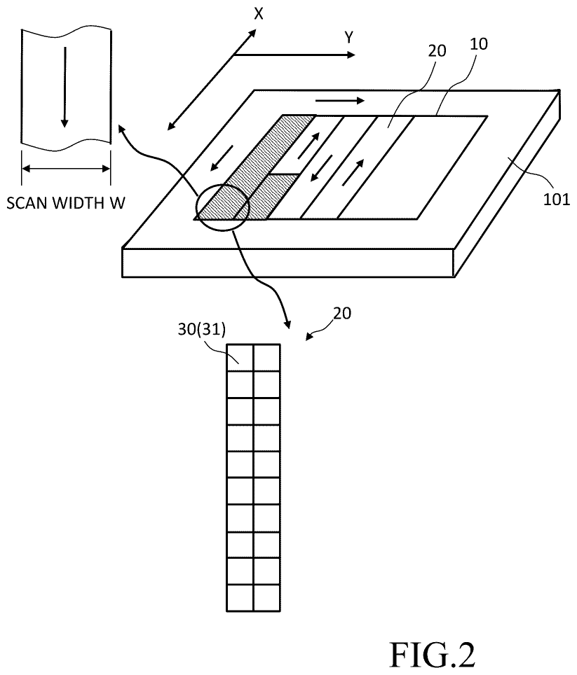

FIG. 2 is a conceptual diagram illustrating an inspection region according to the first embodiment. As shown in FIG. 2, an inspection region 10 (the entire inspection region) of the substrate 101 is virtually divided into a plurality of strip-shaped inspection stripes 20 (stripe region) each having a width W in the y direction, for example, where the width W is a scan width of the imaging sensor 105. The inspection apparatus 100 acquires an image (stripe region image) with respect to each inspection stripe 20.

Specifically, with respect to each of the inspection stripes 20, the inspection apparatus 100 acquires (captures) an image of a figure pattern arranged in the inspection stripe 20 concerned, with a laser light (inspection light), while imaging in the longitudinal direction (the x direction) of the inspection stripe 20 concerned. In order to prevent a missing image, it is preferable that a plurality of inspection stripes 20 are set such that adjacent inspection stripes 20 overlap with each other by a predetermined margin width.

The imaging sensor 105 that continuously moves relatively in the x direction by the movement of the XYθ table 120 acquires optical images. The imaging sensor 105 continuously acquires optical images each having the scan width W as shown in FIG. 2. According to the first embodiment, after acquiring an optical image at one inspection stripe 20, the imaging sensor 105 moves in the y direction to the position of the next inspection stripe 20, and similarly acquires another optical image having the scan width W continuously while moving in the direction reverse to the last image acquiring direction. Thereby, the image acquiring is repeated in the forward (FWD) and backward (BWD) directions, namely changing the direction reversely when advancing and returning.

In an actual inspection, as shown in FIG. 2, the stripe region image of each inspection stripe 20 is divided into images of a plurality of rectangular (including square) frame regions 30. Then, inspection is performed for each image of the frame region 30. For example, it is divided into the size of 512×512 pixels. Therefore, a reference image to be compared with a frame image 31 of the frame region 30 is similarly generated for each frame region 30.

The direction of the image acquiring is not limited to repeating the forward (FWD) and backward (BWD) movement. Images may be acquired in a fixed one direction. For example, FWD and FWD may be repeated, or alternatively, BWD and BWD may be repeated.

As described above, the inspection apparatus 100 includes, in addition to the inspection optical system 176 (reflection inspection optical system and/or transmission inspection optical system), the focusing mechanism 131 which detects a height-wise displacement of the substrate 101, being an inspection target object with respect to the inspection optical system 176.

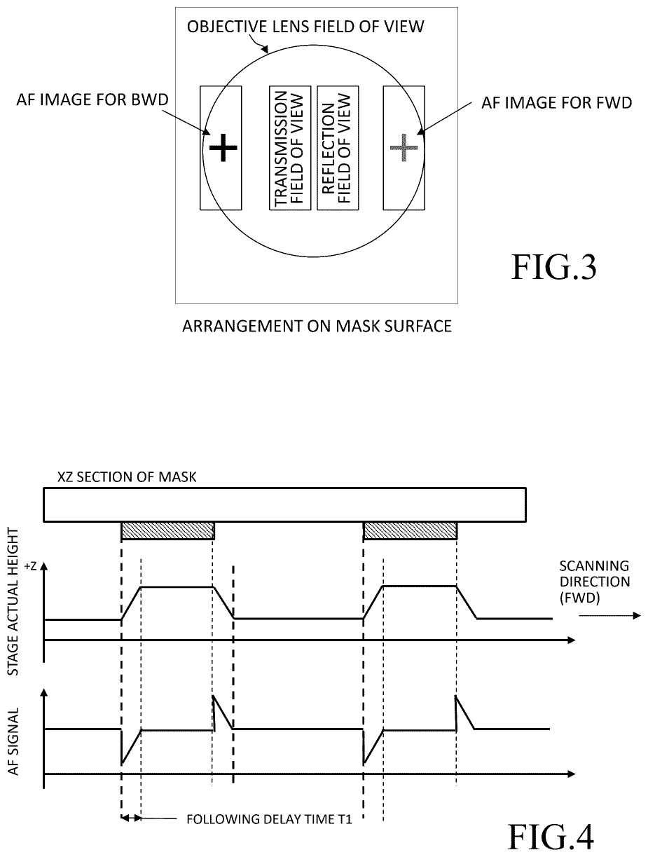

FIG. 3 is an illustration showing an example of each region on the substrate surface according to a comparative example of the first embodiment. In FIG. 3, when scanning each inspection stripe, the substrate is irradiated with each inspection light such that the transmission field of view (slit image) of an inspection light for transmission inspection and the reflection field of view (slit image) of an inspection light for reflection inspection are aligned in a scanning direction with respect to a target inspection stripe. At this time, the substrate is irradiated with a light of an AF image for autofocus (AF) such that the AF image is arranged close to each inspection field of view and ahead in a scanning direction. FIG. 3 shows the case where both the AF image for FWD and the AF image for BWD are arranged. Then, using a confocal sensor, autofocusing is performed by adjusting the stage height to focus the AF image arranged ahead in a scanning direction. By this, a pattern image on the substrate is imaged in focus, in each inspection field of view.

FIG. 4 is an illustration for explaining an example of an autofocusing operation according to a comparative example of the first embodiment. When an AF image approaches a pattern on the substrate, the focus height position of the AF image is shifted by the height of the pattern. Therefore, an AF signal indicating the shifted amount is output from the confocal sensor. Based on the AF signal, the pattern position is focused by heightening the stage by the amount shifted from the focus height. However, even if the AF signal is processed at a high speed, a follow-up delay of the stage movement occurs as shown in FIG. 4. Consequently, in each inspection field of view, there occurs a case where imaging is performed in a defocused state. For this reason, since the image of an end portion which reaches faster, in a scanning direction, than the other of both the ends of the pattern becomes blur, the pattern size and the pattern position deviate, which causes a problem that the deviation is misidentified as a defect, or omission occurs in defect detection.

In order to cope with this problem, it is necessary to obtain the height position of the pattern forming surface, where a change occurs depending on a pattern, sufficiently before the inspection field of view captures an image of the pattern. For example, it can be thought to arrange the irradiation position of an AF image further ahead, in a scanning direction, than the distance corresponding to a follow-up delay of the stage movement. However, if the irradiation position of an AF image is arranged sufficiently ahead in a scanning direction, there is a possibility the irradiation position becoming out of the field of view of the objective lens of the illumination optical system. Consequently, it becomes necessary to enlarge the size of the objective lens. Furthermore, the distance, ahead in a scanning direction, where the irradiation position of an AF image should be arranged varies depending on a relation with the stage speed. Therefore, it is difficult to determine uniquely specifically.

Then, according to the first embodiment, focusing is performed by a method different from the autofocusing operation by an AF image close to an inspection field of view. In the case where the k-th (k being an integer of 1 or more) inspection stripe 20 (stripe region) is scanned with an inspection light, the inspection apparatus 100 of the first embodiment sets the irradiation positions of an inspection light and a measuring light on the substrate 101 such that the (k+m)th (m being an integer of 1 or more) inspection stripe is scanned with a measuring light for measuring a focus deviation. It is specifically described below.

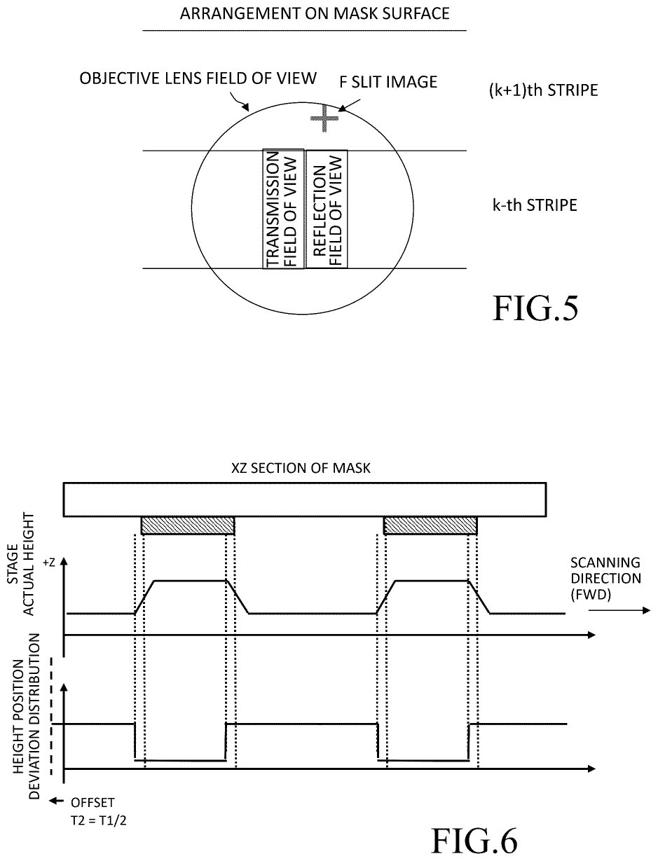

FIG. 5 is an illustration showing an example of each region on the substrate surface according to the first embodiment. In FIG. 5, when scanning each inspection stripe, the substrate is irradiated with each inspection light such that a transmission field of view (slit image) of an inspection light for transmission inspection and a reflection field of view (slit image) of an inspection light for reflection inspection are aligned in a scanning direction with respect to a target inspection stripe. If only one inspection of the transmission inspection and the reflection inspection is performed, it is sufficient that the substrate is irradiated with an inspection light so that only the one concerned in the transmission field of view and the reflection field of view may be arranged. At this process, the substrate 101 is irradiated with a light (measuring light) of an F slit image such that a focus (F) slit image for measuring a height deviation amount of the substrate 101 deviated from the focus height is arranged at he (k+m)th inspection stripe 20, which is ahead by at least one inspection stripe from the k-th inspection stripe where an inspection field of view is to be arranged. Thereby, while performing scanning for inspecting the k-th inspection stripe 20, it is possible to simultaneously perform scanning for measuring the amount of a height position deviation of the (k+m) inspection stripe 20 deviated from the focus height position.

In the scanning operation for measuring a height deviation, a focus signal indicating a deviation from the focus position of an F slit image is output using a confocal sensor, and this information is accumulated. In each inspection field of view, by changing the stage height position in accordance with a height position deviation amount distribution obtained by the scanning operation having already been performed for measuring a height deviation, a pattern image on the substrate can be imaged in focus.

FIG. 6 is an illustration showing an example of a focusing operation according to the first embodiment. When performing an operation for a target inspection stripe 20 with an inspection light of the inspection field of view, since the height position distribution of the target inspection stripe is already known, the stage height can be adjusted in accordance with the height position deviation amount distribution. In that case, if changing the stage height is started when the inspection field of view approaches the pattern position, a follow-up delay of the stage occurs similarly to the comparative example. Therefore, in advance, the pattern position is made to be offset with respect to a scanning direction. Specifically, in the height position deviation amount distribution, the pattern position is wholly offset to the near side in the scanning direction by the time distance equivalent to a half of the stage height moving time. This means to read the height position deviation amount distribution in advance by ½ time of the follow-up delay time of the stage, and to operate the stage. Thereby, at the time when the inspection field of view approaches a pattern, the stage height has already moved to the intermediate position of the movement distance. Therefore, the follow-up delay of the stage movement can be prevented or reduced. As a result, defocused imaging in each inspection field of view can be prevented or reduced.

Here, if offsetting is performed by all the distance equivalent to a follow-up delay, the stage height position moves to the focusing height, which is under the condition of there being no pattern, although actually the pattern still exists at the end of the opposite side of the pattern. For this reason, since the image of the final end portion which reaches later, in a scanning direction, than the other of both the ends of the pattern becomes blurring, the pattern size and the pattern position deviate, which results in misidentification of the deviation as a defect, or omission of defect detection. Therefore, according to the first embodiment, offsetting is performed by ½ of the follow-up delay distance, and thus, the deviation amounts of the focus height at the end which reaches faster and at the end which reaches later with respect to the scanning direction over the pattern can be made the same while reducing them.

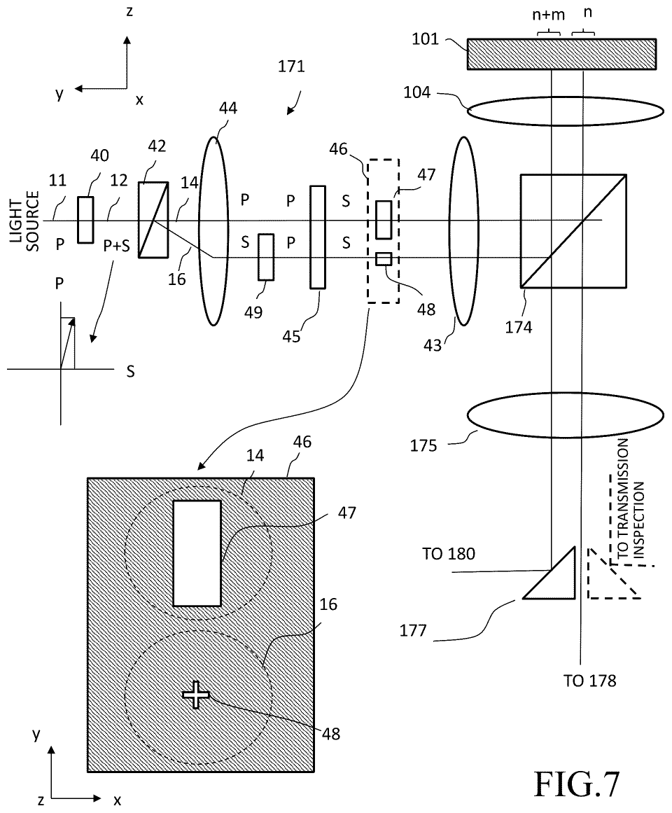

FIG. 7 is an illustration showing an example of a configuration of an illumination optical system according to the first embodiment. The light emitted from the light source 103 is separated into the light for transmission inspection and the light for reflection inspection. FIG. 7 shows an example of the configuration of the reflection illumination optical system 171 on which a light 11 for reflection inspection is incident.

The reflection illumination optical system 171 includes a half-wave plate 40, a Rochon prism 42, a collimating lens 44, a half-wave plate 49, a half-wave plate 45, a slit plate 46, and a lens 43.

In the example of FIG. 7, the polarization direction (electric field oscillation direction) of the light 11 to be incident on the reflection illumination optical system 171 is adjusted in a fixed direction by an optical element (not shown). For example, the light 11 (P wave) whose polarization direction is 90° from the x axis, for example, with respect to a plane (x-z plane) orthogonal to the travelling direction of the light 11 enters the reflection illumination optical system 171.

The polarization direction of the light 11 (the first light) incident on the half-wave plate 40 is changed by adjusting the angle of the half-wave plate 40. In this process, as shown in FIG. 7, the adjustment is performed such that the angle makes, for example, the P-wave component for an inspection light much, and, for example, the S-wave component for a measuring light for measuring a height deviation less. A light 12 emitted from the half-wave plate 40 and including, for example, a P-wave component and an S-wave component enters the Rochon prism 42, and separates the trajectory of the P-wave component from the trajectory of the S-wave component. For example, the P-wave component is output to go straight, and the S-wave component is output to go aslant. By this, it is possible to separate into an inspection light 14 and a measuring light 16. Both the inspection light 14 and the measuring light 16 enter the collimating lens 44, and are refracted to have parallel trajectories mutually. For example, the inspection light 14 passes through the center of the collimating lens 44, and is output straight. The measuring light 16 passes through the outer peripheral part of the collimating lens 44, and is refracted in a converging direction, and output in the direction parallel to the inspection light 14.

The inspection light 14 having passed through the collimating lens 44 becomes the polarization direction of the P wave, for example. In contrast, the measuring light 16 having passed through the collimating lens 44 becomes the polarization direction of the S wave, for example. Then, the measuring light 16 enters the half-wave plate 49, and is converted into a light (e.g., P wave) in the polarization direction being the same as that of the inspection light 14, and is output. Both the inspection light 14 and the measuring light 16 enter the half-wave plate 45, and after being converted into, for example, S waves and output, enter the slit plate 46 in parallel. In the slit plate 46, a slit opening 47 being, for example, a rectangle is formed in order to form a reflection field of view for reflection inspection. Furthermore, in the slit plate 46, a slit opening 48 is formed which restricts passage of a measuring light for measuring the amount of height position deviation of the substrate 101 from the focus height. Preferably, a cross pattern opening is used as the slit opening 48, for example. The inspection light 14 irradiates the whole of the slit opening 47. Similarly, the measuring light 16 irradiates the whole of the slit opening 48. While keeping the state of the polarization direction of the S wave, the inspection light 14 of a reflection field of view slit image having passed through the slit opening 47 enters the beam splitter 174 through the lens 43, for example. Similarly, while keeping the state of the polarization direction of the S wave, for example, the light 16 of a focus slit image (F slit image) having passed through the slit opening 48 enters the beam splitter 174 through the lens 43, for example.

The reflection illumination optical system 171 irradiates the substrate 101 with the measuring light 16 which has passed through the slit plate 46. Furthermore, the reflection illumination optical system 171 irradiates the substrate 101 with the inspection light 14. Specifically, the inspection light 14 and the measuring light 16 which entered the beam splitter 174 are reflected by the beam splitter 174, and applied to the substrate 101 by the magnifying optical system 104. Since the inspection light 14 and the measuring light 16 are image-focused by the same lens, the focus height positions of the inspection light 14 and the measuring light 16 are the same. Thus, in the reflection inspection, the beam splitter 174 and the magnifying optical system 104 function as a part of the reflection illumination optical system 171.

The inspection light 14 irradiates the k-th inspection stripe 20, and, simultaneously, the measuring light 16 irradiates the (k+m)th inspection stripe 20. The light corresponding to the inspection light 14 reflected from the substrate 101 passes through the magnifying optical system 104, the beam splitter 174, and the first image forming lens 175, and travels to the image forming optical system 178. The light corresponding to the measuring light 16 reflected from the substrate 101 passes through the magnifying optical system 104, the beam splitter 174, and the first image forming lens 175, is reflected by the separating mirror 177, and travels to the focusing optical system 180.

In the case of performing a transmission inspection at the same time, as depicted by the dotted line in FIG. 7, the k-th inspection stripe 20 is irradiated with an inspection light for transmission inspection, and the light having passed through the substrate 101 passes through the magnifying optical system 104, the beam splitter 174, and the first image forming lens 175, is reflected by the separating mirror for transmission inspection, and travels to the focusing optical system (not shown) for transmission inspection.

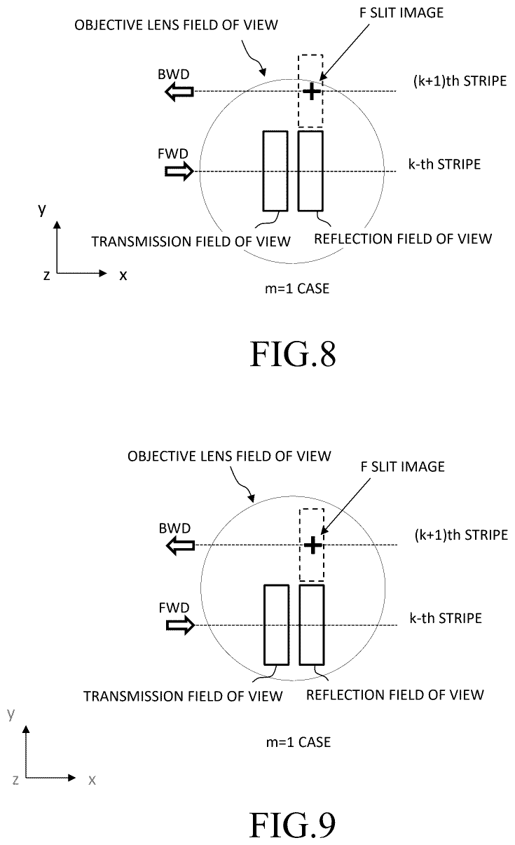

FIG. 8 is an illustration showing an example of a positional relationship among an inspection field of view, a focus slit image, and an objective lens field of view according to the first embodiment. FIG. 8 shows, when m=1, the position of the F slit image in the case where the transmission field of view and reflection field of view, serving as an inspection field of view, aligned in the x direction are arranged at the center of the objective lens field of view. In the example of FIG. 8, the F slit image is arranged in the y direction with respect to the reflection field of view.

FIG. 9 is an illustration showing another example of a positional relationship among an inspection field of view, a focus slit image, and an objective lens field of view according to the first embodiment. FIG. 9 shows the case where, when m=1, the center position between the inspection field of view, including the transmission field of view and the reflection field of view, and an F slit image is arranged at the center of the objective lens field of view. In the example of FIG. 9, the F slit image is arranged in the y direction with respect to the reflection field of view, and located at the center of the field of view having the same size as the reflection field of view.

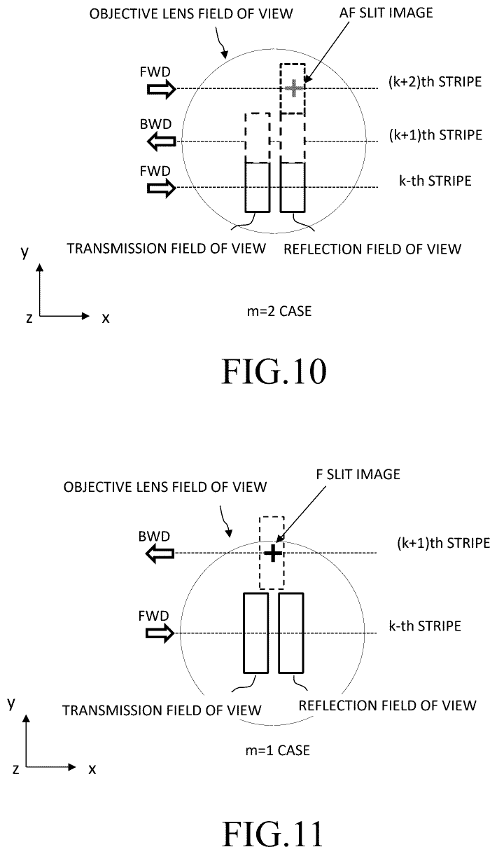

FIG. 10 is an illustration showing another example of a positional relationship among an inspection field of view, a focus slit image, and an objective lens field of view according to the first embodiment. FIG. 10 shows the case where, when m=2, the center position between the inspection field of view, including the transmission field of view and the reflection field of view, and an F slit image is arranged at the center of the objective lens field of view. In the example of FIG. 10, the F slit image is arranged in the y direction, having a space for one inspection stripe, with respect to the reflection field of view, and located at the center of the field of view having the same size as the reflection field of view. Thus, as described above, if the size of the objective lens field of view can include a region of three or more stripe widths, it is also preferable to arrange an F slit image at the inspection stripe 20 being posterior by two or more inspection stripes 20 to the target inspection stripe 20 of the inspection field of view. Alternatively, it is also preferable to similarly arrange the F slit image after increasing the size of the objective lens field of view or decreasing the size of the inspection field of view (illumination field). For example, when m=2, at the time of performing an FWD inspection for the k-th inspection stripe 20, it is possible to measure a height deviation of the inspection stripe which is two after the k-th inspection stripe and for which the FWD inspection is to be next performed, by the FWD direction operation being the same as the FWD inspection operation at the inspection.

FIG. 11 is an illustration showing another example of a positional relationship among an inspection field of view, a focus slit image, and an objective lens field of view according to the first embodiment. FIG. 11 shows the position of an F slit image in the case where, when m=1, the transmission field of view and reflection field of view, serving as an inspection field of view, are arranged at the center of the objective lens field of view. In the example of FIG. 11, the F slit image is arranged in the y direction with respect to the center position between the transmission field of view and the reflection field of view. By this configuration, a focus deviation can be measured at the same position whether the scanning direction is FWD or BWD.

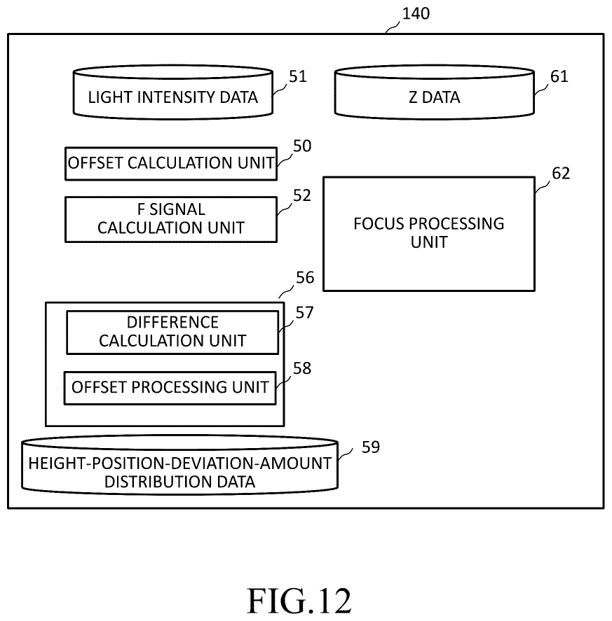

FIG. 12 is a block diagram showing an example of an internal configuration of a focus control circuit according to the first embodiment. In FIG. 12, in the focus control circuit 140, there are arranged storage devices 51, 59 and 61 such as magnetic disk drives, an offset calculation unit 50, a focus signal calculation unit 52, a height position deviation amount distribution generating unit 56, and a focus processing unit 62. In the height position deviation amount distribution generating unit 56, there are arranged a difference calculation unit 57 and an offset processing unit 58. Each of the “units” such as the offset calculation unit 50, the focus signal calculation unit 52, the height position deviation amount distribution generating unit 56 (the difference calculation unit 57 and the offset processing unit 58), and the focus processing unit 62 includes processing circuitry. The processing circuitry includes an electric circuit, a computer, a processor, a circuit board, a quantum circuit, a semiconductor device, or the like. Each of the “units” may use common processing circuitry (the same processing circuitry), or different processing circuitry (separate processing circuitry). Input data needed in the offset calculation unit 50, the focus signal calculation unit 52, the height position deviation amount distribution generating unit 56 (the difference calculation unit 57 and the offset processing unit 58), and the focus processing unit 62, or calculated results are stored in a memory (not shown) in the focus control circuit 140 or in the memory 111 each time.

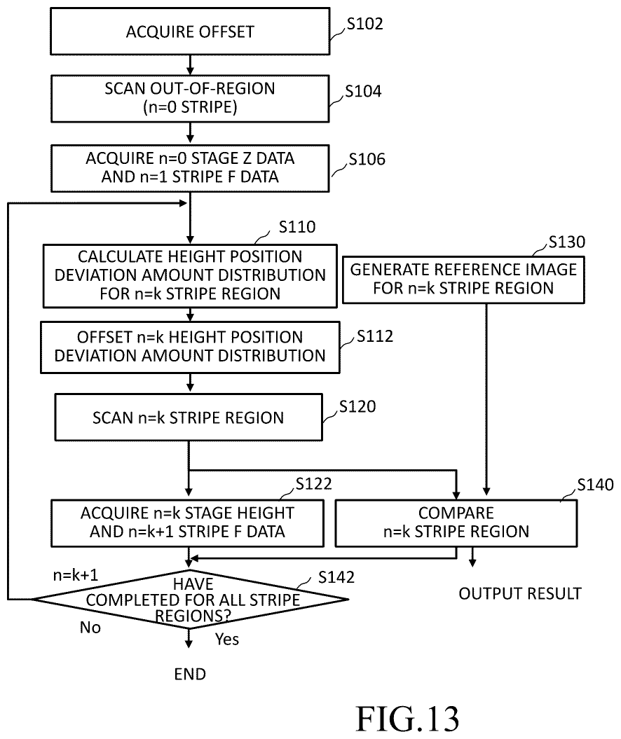

FIG. 13 is a flowchart showing an example of main steps of an inspection method according to the first embodiment. In FIG. 13, the inspection method of the first embodiment executes a series of steps: an offset acquisition step (S102), an out-of-region scan step (S104), a z data and F data acquisition step (S106), a height position deviation amount distribution calculation step (S110), an offset step (S112), a scanning step (S120), a z data and F data acquisition step (S122), a reference image generation step (S130), a comparison step (S140), and a determination step (S142).

In the offset acquisition step (S102), the offset calculation unit 50 calculates an offset amount based on the operation delay time of the XYθ table 102 responsive to a focus signal. Specifically, it operates as follows: First, in a state where the substrate 101 to be inspected is placed on the XYθ table 102, an operation delay time of the XYθ table 102 responsive to a focus signal is measured using a pattern for calibration. The height position of the XYθ table 102 is measured by the position sensor 134 from the time when the focus processing unit 62 outputs, based on a focus signal, a drive command to the Z drive mechanism 132 to the time when the Z drive mechanism 132 has actually finished to move the height of the XYθ table 102. Then, ½ of the distance equivalent to the operation delay time of the stage responsive to a focus signal measured is calculated as an offset amount. The offset amount at the time of FWD operation and the offset amount at the time of BWD operation are individually calculated. The calculated offset amount is stored in the storage device 59 and the like, for example.

In the out-of-region scan step (S104), the optical image acquisition mechanism 150 scans, with an inspection light, the outside of the inspection region 10 where an F slit image is located at the first inspection stripe 20. For example, in the case of an F slit image being arranged when m=1, scanning is performed over the region immediately previous to the first inspection stripe 20, (for example, the 0th (n=0) inspection stripe). In this case, it is not necessary to perform focus adjustment because of being outside the inspection region 10. Therefore, in the state where the height of the XYθ table 102 is fixed, for example, to the focus height position, the 0th inspection stripe is scanned with an inspection light while the Z drive mechanism 132 is stopped. By this operation, the light amount sensor 185 measures the light amount at the front focus position of a light reflected from the first inspection stripe 20 scanned with a measuring light of the F slit image. Similarly, the light amount sensor 187 measures the light amount at the back focus position. Furthermore, simultaneously, the position sensor 134 measures the height position of the XYθ table 102 at the time of scanning the 0th (n=0) inspection stripe.

The appropriate light source 103 emits a laser light (e.g., DUV light) serving as an inspection light, whose wavelength is equal to or shorter than that of a light in the ultraviolet region, to the beam splitter 174 by the reflection illumination optical system 171. The irradiated laser light includes an inspection light of the reflection field of view and a measuring light of the F slit image. The irradiated laser light is reflected from the beam splitter 174, and applied to the substrate 101 by the magnifying optical system 104. The light reflected from the substrate 101 passes through the magnifying optical system 104, the beam splitter 174, and the first image forming lens 175, and is applied to the separating mirror 177. The reflected light corresponding to a measuring light reflected from the separating mirror 177 enters the focus optical system 180.

The light incident on the focus optical system 180 is refracted in the condensing direction by the image forming optical system 181, and applied to the beam splitter 182. The light transmitted through the beam splitter 182 is partially restricted by the slit plate 184 at the front focus position, and then, the amount of light which has passed through the slit plate 184 is measured by the light amount sensor 185. The light branched by the beam splitter 182 is partially restricted by the slit plate 186 at the back focus position, and then, the amount of light which has passed through the slit plate 186 is measured by the light amount sensor 187. By this, the amount of light at the front focus position and that at the back focus position can be measured. Each light amount data (light intensity data) of the amount of light at the front focus position and that at the back focus position measured during scanning is stored, to be related to measurement coordinates, in the storage device 51.

In the z data and F data acquisition step (S106), the focus signal calculation unit 54 calculates a focus signal, using the measured amount of light at the front focus position and that at the back focus position. A focus signal (f) is defined by the following equation (1) using the light amount A at the front focus position, and the light amount B at the back focus position.

$$f = ( A - B ) / ( A + B ) \qquad ( 1 )$$

A focus signal distribution of the inspection stripe 20 scanned with a measuring light is stored in the storage device 51, for example. Here, the focus signal distribution of the first (n=1) inspection stripe 20 is acquired. Furthermore, a height position distribution of the XYe table 102 at the time of the inspection stripe 20 being scanned with an inspection light is stored in the storage device 61. Here, since focus adjustment has not been performed, a flat distribution of the focus height position is measured.

Although, in the example described above, focus adjustment is not performed when scanning the 0th (n=0) inspection stripe with an inspection light, it is not limited thereto. In accordance with a focus signal detected by scanning the 0th (n=0) inspection stripe 20 with a measuring light, under the control of the focus processing unit 62, it is also acceptable to perform an autofocus operation by the Z drive mechanism 132 by variably driving the height position of the XYe table 102. In that case, regardless of condition of the surface equivalent to the pattern forming surface of the 0th (n=0) inspection stripe 20, autofocusing is carried out such that the pattern forming surface of the first (n=1) inspection stripe 20 is always at the focus height position.

In the height position deviation amount distribution calculation step (S110), the height position deviation amount distribution generating unit 56 generates, for each inspection stripe 20 (stripe region), a height position deviation amount distribution of the pattern forming surface of the inspection stripe 20 concerned, deviated from the focus height position of a measuring light. In other words, the height position deviation amount distribution generating unit 56 calculates a distribution of a height position deviation amount of the pattern forming surface of the k-th (n=k) inspection stripe 20 scanned with a measuring light, deviated from the focus height position. First, a distribution of a height position deviation amount of the pattern forming surface of the first (n=1) inspection stripe 20, deviated from the focus height position is calculated.

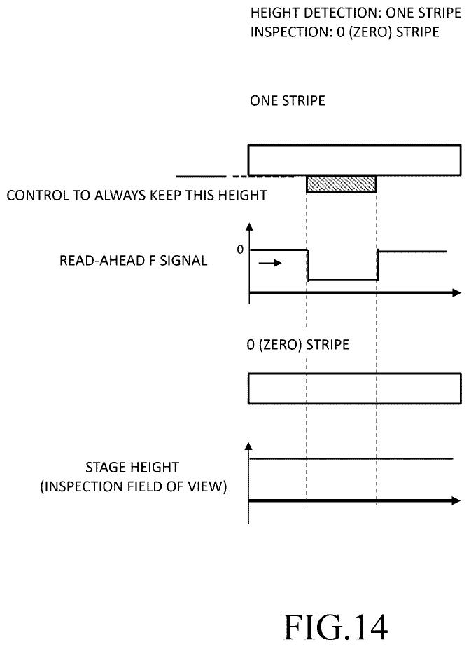

FIG. 14 is an illustration showing an example of a height distribution of the XYθ table 102 (stage) at the 0th (n=0) inspection stripe, and an example of a height position deviation distribution at the first (n=1) inspection stripe according to the first embodiment. As described above, since no focus adjustment is performed for the 0th (n=0) inspection stripe, the height position of the XYθ table 102 (stage) is fixed as shown in FIG. 14. In contrast, at the first (n=1) inspection stripe for which the height position of the pattern forming surface has been read ahead, the value of the focus signal (F signal) becomes, for example, decreased when approaching a pattern end from a position where no pattern exits, thereby indicating that the height position of the pattern forming surface becomes lower. While the pattern exists, the value of the focus signal is still maintained to be decreased. Then, when passing the pattern end at the opposite side, the value of the focus signal becomes, for example, increased to return to the original value, thereby indicating that the height position of the pattern forming surface becomes higher.

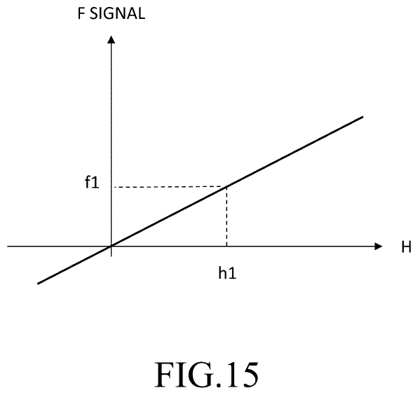

FIG. 15 is an illustration showing an example of a relationship between a focus signal and a stage height position according to the first embodiment. In FIG. 15, the ordinate axis represents a focus signal value, and the abscissa axis represents a stage height position. As shown in FIG. 15, the focus signal based on a light amount detected by a confocal sensor, and the stage height position can be defined as a linearly proportional relation. For example, the optical system is adjusted such that, at the stage height position in the case of the focus signal being zero, the reference surface of the pattern forming surface of the substrate 101 becomes the focus height. In autofocus control, the height position of the pattern forming surface of the substrate 101 is adjusted to be a focus height position by adjusting the stage height to make the focus signal 0 (zero), for example. According to the first embodiment, using this relation, the amount of deviation of the height position of the target inspection stripe 20 deviated from the focus height position is calculated based on a distribution of detected focus signals.

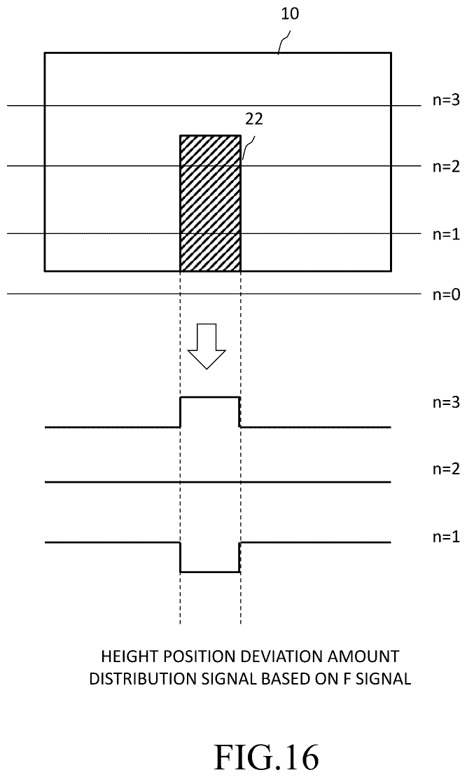

FIG. 16 is an illustration showing an example of a relationship between a pattern forming surface and a height position distribution based on a focus signal according to the first embodiment. In the example of FIG. 16, a figure pattern 22 extending over the first inspection stripe 20 and the second inspection stripe 20 is arranged in the inspection region 10 of the substrate 101.

Scanning the 0th (n=0) inspection stripe 20 with an inspection light is performed in the state where the height position of the XYθ table 102 (stage) is fixed to the focus height position, and simultaneously, a focus signal of the first (n=1) inspection stripe 20 scanned with a measuring light is acquired. Therefore, the focus signal becomes decreased only at the position where the figure pattern 22 exists in the first (n=1) inspection stripe 20, thereby indicating that the height position of the pattern forming surface becomes lower.

Scanning the first (n=1) inspection stripe 20 with an inspection light is performed in the state where the height position of the XYθ table 102 (stage) is focus-controlled based on the height position deviation distribution acquired by the last previous scanning with a measuring light, and simultaneously, a focus signal of the second (n=2) inspection stripe 20 scanned with a measuring light is acquired. In that case, since, at the position where the figure pattern 22 exists in the first (n=1) inspection stripe 20, the height position of the XYθ table 102 (stage) is increased by the film thickness of the figure pattern 22, it becomes the same height position as that at the position where no figure pattern 22 exists. Therefore, the focus signal becomes fixed because the height position of the pattern forming surface does not change even at the position where the figure pattern 22 exists in the second (n=2) inspection stripe 20. Thus, if as it is, the height position deviation distribution of the second (n=2) inspection stripe 20 based on the focus signal is inconsistent with the actual height position deviation distribution. Accordingly, it is needed to perform correction. The method of correction is described later.

Scanning the second (n=2) inspection stripe 20 with an inspection light is performed in the state where the height position of the XYθ table 102 (stage) is focus-controlled based on the height position deviation distribution acquired by the last previous scanning with a measuring light, and simultaneously, a focus signal of the third (n=3) inspection stripe 20 scanned with a measuring light is acquired. In that case, since, at the position where the figure pattern 22 exists in the second (n=2) inspection stripe 20, the height position of the XYθ table 102 (stage) is increased by the film thickness of the figure pattern 22, it becomes the same height position as that at the position where no figure pattern 22 exists. Therefore, the value of the focus signal of the third (n=3) inspection stripe 20 in spite of there being no figure pattern 22 becomes increased at the position where the figure pattern 22 exists in the second (n=2) inspection stripe 20, thereby indicating that the height position of the pattern forming surface becomes higher. Thus, if as it is, the height position deviation distribution of the third (n=3) inspection stripe 20 based on the focus signal is inconsistent with the actual height position deviation distribution. Accordingly, it is needed to perform correction. The method of correction is described later.

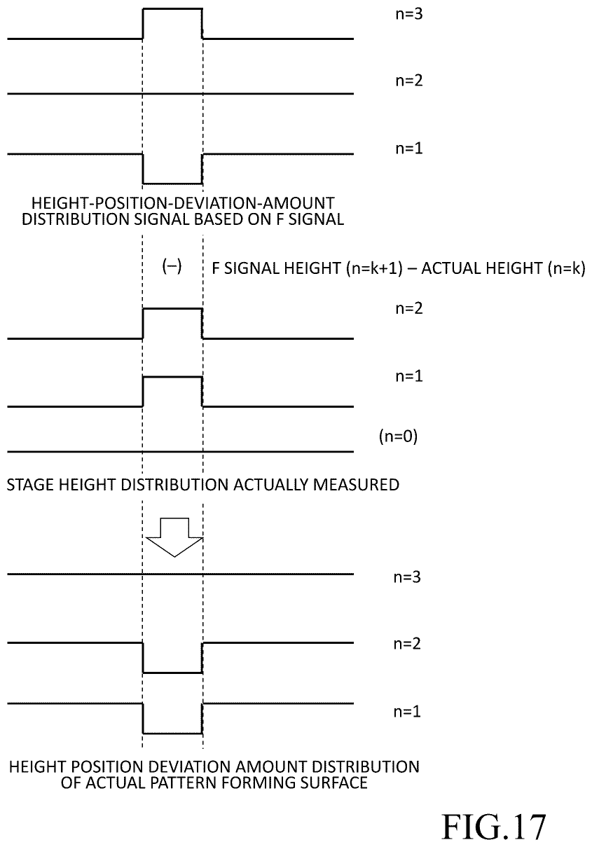

FIG. 17 is an illustration for explaining a method of calculating a height position deviation distribution of an actual pattern forming surface according to the first embodiment. As described above, if the amount of a height position deviation is measured by scanning the inspection stripe 20 with a measuring light in the state in which the height position of the XYθ table 102 (stage) changes, an exact deviation amount distribution cannot be acquired. Therefore, it is necessary to take into consideration the change amount of the height position of the XYθ table 102 (stage) in the inspection stripe 20 scanned with an inspection light simultaneously with performing scanning with a measuring light.

Then, the difference calculation unit 57 calculates a difference distribution obtained by subtracting the stage height position deviation distribution, deviated from the focus height position, of the k-th (n=k) inspection stripe 20 scanned with an inspection light from the height position deviation distribution, based on a focus signal, of the (k+m)th (n=k+m) inspection stripe 20 scanned with a measuring light, performed simultaneously with the scanning with the inspection light, as a height position deviation distribution of the (k+m)th (n=k+m) inspection stripe 20 scanned with the measuring light. Thus, the stage height position deviation distribution can be obtained as a difference between the stage height measured by the position sensor 134 and the focus height position. Specifically, it operates as described below.

In scanning the 0th (n=0) inspection stripe 20 with an inspection light, since the height position of the XYθ table 102 (stage) is fixed to the focus height position, the actually measured stage height position deviation distribution of the XYθ table 102 (stage) is fixed zero. Therefore, the difference obtained by subtracting the stage height position deviation distribution of the XYθ table 102 (stage) at the time of scanning the 0th (n=0) inspection stripe 20 with an inspection light from the height position deviation distribution, based on a focus signal, of the first (n=1) inspection stripe 20 scanned with a measuring light, performed simultaneously with the scanning with the inspection light, thereby resulting in obtaining a height position deviation distribution, from the focus height position, of the first (n=1) inspection stripe 20. Thus, as shown in the actual first (n=1) inspection stripe 20, the height position becomes lower at the position where the figure pattern 22 exists.

In scanning the first (n=1) inspection stripe 20 with an inspection light, since the height position of the XYθ table 102 (stage) becomes higher at the position where the figure pattern 22 exists, the actually measured stage height position deviation distribution of the XYθ table 102 (stage) is increased at the position where the figure pattern 22 exists. Therefore, the difference obtained by subtracting the stage height position deviation distribution of the XYθ table 102 (stage) at the time of scanning the first (n=1) inspection stripe 20 with an inspection light from the height position deviation distribution, based on a focus signal, of the second (n=2) inspection stripe 20 scanned with a measuring light, performed simultaneously with the scanning with the inspection light, thereby resulting in obtaining a height position deviation distribution, from the focus height position, of the second (n=2) inspection stripe 20. Since the increased height of the actually measured stage height position deviation distribution of the XYθ table 102 (stage) is subtracted, as shown in the actual second (n=2) inspection stripe 20, in the difference, the height position becomes lower at the position where the figure pattern 22 exists.

In scanning the second (n=2) inspection stripe 20 with an inspection light, since the height position of the XYe table 102 (stage) becomes higher at the position where the figure pattern 22 exists, the actually measured stage height position deviation distribution of the XYθ table 102 (stage) is increased at the position where the figure pattern 22 exists. Therefore, the difference obtained by subtracting the stage height position deviation distribution of the XYθ table 102 (stage) at the time of scanning the second (n=2) inspection stripe 20 with an inspection light from the height position deviation distribution, based on a focus signal, of the third (n=3) inspection stripe 20 scanned with a measuring light, performed simultaneously with the scanning with the inspection light, thereby resulting in obtaining a height position deviation distribution, from the focus height position, of the third (n=3) inspection stripe 20. Since the increased height of the actually measured stage height position deviation distribution of the XYθ table 102 (stage) is subtracted, as shown in the actual third (n=3) inspection stripe 20, in the difference, the height position becomes the one where no figure pattern 22 exists.

In the offset step (S112), with respect to the actual height position deviation amount distribution of the (k+m)th (n=k+m) inspection stripe 20, which is obtained by the difference, the offset processing unit 58 (a part of the height position deviation amount distribution generating unit) wholly offsets, in a direction parallel to a scanning direction of scanning the inspection stripe, the position(s) (time position) of the scanning direction at which the height position changes. Specifically, it operates as described below.

In the case of scanning the first (n=1) inspection stripe 20 with an inspection light, as described above, the height position of the XYθ table 102 (stage) is focus-controlled in accordance with the already acquired height position deviation amount distribution of the first (n=1) inspection stripe 20, deviated from the focus height position. However, as described above, if changing the height position of the XYθ table 102 (stage) is started when approaching the actual pattern end, blurring occurs due to an operation delay of the stage. Therefore, as explained in FIG. 6, the offset processing unit 58 generates a height position deviation amount distribution in which the position of height change by a pattern is offset to the near side in the scanning direction by an acquired offset amount.

Thus, the height position deviation distribution of the (k+m)th (n=k+m) inspection stripe 20 after offset can be acquired. If in the case of scanning the 0th inspection stripe 20 with an inspection light, a height position deviation distribution of the first inspection stripe 20 after offset can be acquired as the (k+m)th (n=k+m) inspection stripe 20. The height position deviation distribution of the (k+m)th (n=k+m) inspection stripe 20 after offset is stored in the storage device 59.

In the scanning step (S120), the optical image acquisition mechanism 150 scans the k-th (n=k) inspection stripe 20 with an inspection light, and the (k+m)th (n=k+m) inspection stripe 20 with a measuring light. When scanning the k-th (n=k) inspection stripe 20 with the inspection light 14, the height position of the pattern forming surface of the k-th (n=k) inspection stripe 20 is adjusted to the focus height position by variably controlling the height position of the XYθ table 102 in accordance with the already acquired height position deviation distribution of the k-th (n=k) inspection stripe 20. The actual height position of the XYe table 102 during scanning the k-th (n=k) inspection stripe 20 with the inspection light 14 is measured by the position sensor 134. Data (z data) of the measured actual height position of the XYθ table 102 is stored in the storage device 61. Then, the optical image acquisition mechanism 150 images, for each inspection stripe 20, a stripe region image by the imaging sensor 105. In other words, the optical image acquisition mechanism 150 images a stripe region image of the k-th (n=k) inspection stripe 20 by the imaging sensor 105. Specifically, it operates as described below.

First, the XYθ table 102 is moved to the position where the target k-th (n=k) inspection stripe 20 can be imaged. Then, the table control circuit 114 (stage control unit) controls the movement of the XYθ table 102 (stage), for each inspection stripe 20, such that the inspection stripe 20 concerned is scanned with the inspection light 14. In other words, the table control circuit 114 (stage control unit) controls the movement of the XYθ table 102 (stage) so that the target k-th (n=k) inspection stripe 20 can be scanned with the inspection light 14.

In performing a reflection inspection, the beam splitter 174 is irradiated, by the reflection illumination optical system 171, with a laser light (e.g., DUV light) serving as the reflection inspection light 14, which is a part of a light emitted from the light source 103 and whose wavelength is equal to or shorter than that of a light in the ultraviolet region, and with the measuring light 16, which is another part of the light emitted from the light source 103, for measuring a deviation amount of the height position of the substrate 101 from the focus height. The inspection light 14 and measuring light 16 having irradiated are reflected from the beam splitter 174, and applied to the substrate 101 by the magnifying optical system 104. Thus, the substrate 101 is irradiated with the inspection light 14 of a reflection field of view and the measuring light 16 of an F slit image as described above. A light corresponding to the inspection light 14 reflected from the substrate 101 passes through the magnifying optical system 104, the beam splitter 174, and the first image forming lens 175, and is focused to form an optical image to be incident on the imaging sensor 105 by the image forming optical system 178.

In the case of simultaneously performing a transmission inspection, the pattern formed on the substrate 101 is irradiated, through the transmission illumination optical system 170, with a laser light (e.g., DUV light) serving as a transmission inspection light, which is another part of the light emitted from the light source 103 and whose wavelength is equal to or shorter than that of a light in the ultraviolet region. Thus, the surface of the substrate 101 is irradiated with a light of a transmission field of view as described above. The light having passed through the substrate 101, as shown in FIG. 7, passes through the magnifying optical system 104, the beam splitter 174, and the first image forming lens 175, travels to a trajectory, which is independent of the reflection inspection light, by a mirror for transmission inspection, and is focused to form an optical image to be incident on an imaging sensor (not shown) by an image forming optical system (not shown).

When imaging this optical image, the Z drive mechanism 132 (height adjustment mechanism) adjusts the height position of the pattern forming surface of the substrate 101 to the focus height position of the inspection light 14 by using a height position deviation amount distribution which is acquired based on applying the measuring light 14 to the substrate 101 and indicates the amount of deviation of the pattern forming surface of the substrate 101 deviated from the focus height position. Specifically, it operates as described below. The focus processing unit 62 controls the Z drive mechanism 132, in accordance with the already acquired height position deviation distribution after offset of the k-th (n=k) inspection stripe 20, such that the height of the pattern forming surface of the k-th (n=k) inspection stripe 20 becomes the focus height position. Then, under such control, the Z drive mechanism 132 adjusts the height position of the mask surface (pattern forming surface) of the substrate 101, which may change with a horizontal direction movement of the XYe table 102, to the focus height position, to be in accordance with the already acquired height position deviation distribution after offset of the k-th (n=k) inspection stripe 20.

The imaging sensor receives a pattern image of the substrate 101 formed by the light having passed through the substrate 101 or reflected from the substrate 101 due to scanning with an inspection light. In other words, in the state where the height position of the pattern forming surface of the substrate 101 is adjusted to the focus height position, the imaging sensor 105 images an optical image of the substrate 101 for inspecting a defect of a figure pattern, by receiving a light reflected from the k-th (n=k) inspection stripe 20 which is irradiated with the inspection light 14 (reflection inspection light). Furthermore, if simultaneously performing a transmission inspection, in the state where the height position of the pattern forming surface of the substrate 101 is adjusted to the focus height position, an imaging sensor (not shown) images an optical image of the substrate 101 for inspecting a defect of a figure pattern, by receiving a light having passed through the k-th (n=k) inspection stripe 20 which is irradiated with a transmission inspection light.

A pattern image focused/formed on the imaging sensor 105 is photoelectrically converted by each photo sensor element of the imaging sensor 105, and further, analog-to-digital (A/D) converted by the sensor circuit 106. Then, data of a pixel value of the k-th (n=k) inspection stripe 20 being a measuring target is stored in the stripe pattern memory 123. Measurement data (pixel data) is, for example, 8-bit unsigned data, and indicates a gray scale level of brightness (light amount) of each pixel.

In the case of simultaneously performing a transmission inspection, similarly, the pattern image focused/formed on an imaging sensor (not shown) is photoelectrically converted by each photo sensor element of the imaging sensor (not shown), and further, analog-to-digital (A/D) converted by a sensor circuit (not shown). Then, data of a pixel value of the k-th (n=k) inspection stripe 20 to be measured is stored in the stripe pattern memory 123 with an identifier indicating being a transmission inspection.

Meanwhile, by performing scanning the k-th (n=k) inspection stripe 20 with the inspection light 14, simultaneously, scanning the (k+m)th (n=k+m) inspection stripe 20 is performed with the measuring light 16. For each inspection stripe 20, the focusing mechanism 131 (height position deviation amount measuring mechanism) receives a light (second light) reflected from the substrate 101 due to scanning the inspection stripe 20 concerned with the measuring light 16, and measures, based on the received light, the amount of deviation of the height position of the pattern forming surface of the inspection stripe 20 concerned deviated from the focus height position of the measuring light 14. In other words, the focusing mechanism 131 receives a light (second light) reflected from the substrate 101 due to scanning the (k+m)th (n=k+m) inspection stripe 20 with the measuring light 16, and measures, based on the received light, the amount of deviation of the height position of the pattern forming surface of the (k+m)th (n=k+m) inspection stripe 20 deviated from the focus height position. Specifically, it operates as described below.

The light corresponding to the measuring light 16 reflected from the substrate 101 passes through the magnifying optical system 104, the beam splitter 174, and the first image forming lens 175, is reflected by the separating mirror 177, and enters the focusing optical system 180. The light incident on the focusing optical system 180 is refracted in the condensing direction by the image forming optical system 181, and applied to the beam splitter 182. The light transmitted through the beam splitter 182 is partially restricted by the slit plate 184 at the front focus position, and then, the amount of the light which has passed through the slit plate 184 is measured by the light amount sensor 185. The light branched by the beam splitter 182 is partially restricted by the slit plate 186 at the back focus position, and then, the amount of the light which has passed through the slit plate 186 is measured by the light amount sensor 187. By this, the amount of light at the front focus position and that at the back focus position can be measured. Each light amount data (light intensity data) of the light amount at the front focus position and that at the back focus position measured during scanning the (k+m)th (n=k+m) inspection stripe 20 is stored, to be related to measurement coordinates of the (k+m)th (n=k+m) inspection stripe 20, in the storage device 51.

In the z data and F data acquisition step (S122), the focus signal calculation unit 54 calculates a focus signal by using the light amount at the front focus position and the light amount at the back focus position which are measured in the (ktm)th (n=k+m) inspection stripe 20. A focus signal (f) is defined by the equation (1) described above using the light amount A at the front focus position and the light amount B at the back focus position. The storage device 51 and the focus signal calculation unit 54 configure a part of the confocal sensor. Therefore, the confocal sensor measures the light amount (the first light amount) at the front focus position and the light amount (the second light amount) at the back focus position of the light incident on the focusing optical system 180, and outputs a focus signal (parameter) capable of calculating the amount of deviation of the height position, using the light amount at the front focus position and that at the back focus position.

Distribution of focus signals of the (k+m)th (n=k+m) inspection stripe 20 scanned with the measuring light 16 is stored in the storage device 51, for example. Height position distribution of the XYθ table 102 at the time of the k-th (n=k) inspection stripe 20 being scanned with the inspection light 14 is stored in the storage device 61.

In the reference image generation step (S130), the reference image generation circuit 112 generates, using figure pattern data (design data), a reference image serving as a reference. Generating a reference image is carried out, for each inspection stripe 20, in parallel to scanning the inspection stripe 20 concerned. Specifically, it operates as follows: The reference image generation circuit 112 inputs figure pattern data (design data) with respect to each frame region 30 of the target inspection stripe 20, and converts each figure pattern defined by the input figure pattern data into image data in binary or multiple values.

Basic figures defined by the figure pattern data are, for example, rectangles and triangles. For example, figure data which defines the shape, size, position, and the like of each pattern figure is stored by using information, such as coordinates (x, y) of a reference position of the figure, lengths of sides of the figure, and a figure code serving as an identifier for identifying the figure type such as rectangles and triangles.

When design pattern data used as the figure data is input to the reference image generation circuit 112, the data is developed into data of each figure. Then, the figure code, the figure dimensions, and the like indicating the figure shape of each figure data are interpreted. Then, the reference image generation circuit 112 develops each figure data to design pattern image data in binary or multiple values as a pattern to be arranged in squares in units of grids of predetermined quantization dimensions, and outputs the developed data. In other words, the reference image generation circuit 112 reads design data, calculates an occupancy rate of the figure in the design pattern, for each square region obtained by virtually dividing the frame region into squares in units of predetermined dimensions, and outputs n-bit occupancy data (design image data). For example, it is preferable to set one square as one pixel. Assuming that one pixel has a resolution of 1/28 (= 1/256), the occupancy rate in each pixel is calculated by allocating sub-regions, each having 1/256 resolution, which correspond to the region of a figure arranged in the pixel. Then, it becomes 8-bit occupancy data. Such square regions (inspection pixels) can be corresponding to (commensurate with) pixels of measured data.

Next, the reference image generation circuit 112 performs filtering processing, using a filter function, on design image data of a design pattern being image data of a figure.

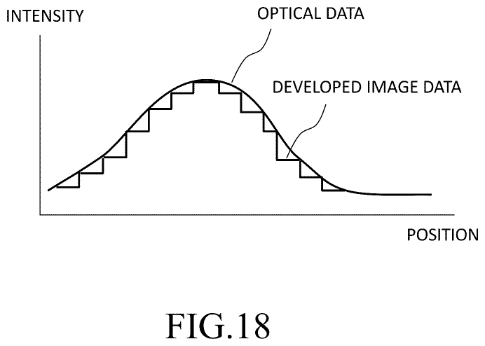

FIG. 18 is a diagram illustrating filter processing according to the first embodiment. Since pixel data of an optical image acquired from the substrate 101 is in a state affected by filtering due to resolution characteristics etc. of the optical system used for image-acquiring, in other words, in an analog state continuously changing, as shown in FIG. 18, for example, the optical image is different from the developed image (design image) whose image intensity (gray scale value) is represented by digital values. By contrast, in figure pattern data, since pattern codes, etc. are used for defining as described above, image intensity (gray scale level) of developed design images may be digital values. Accordingly, the reference image generation circuit 112 performs image processing (filter processing) on the developed image in order to generate a reference image close to the optical image. Thereby, it is possible to match design image data being design side image data, whose image intensity (gray scale level) is in digital values, with image generation characteristics of measured data (optical image). The generated reference image is output to the comparison circuit 108.

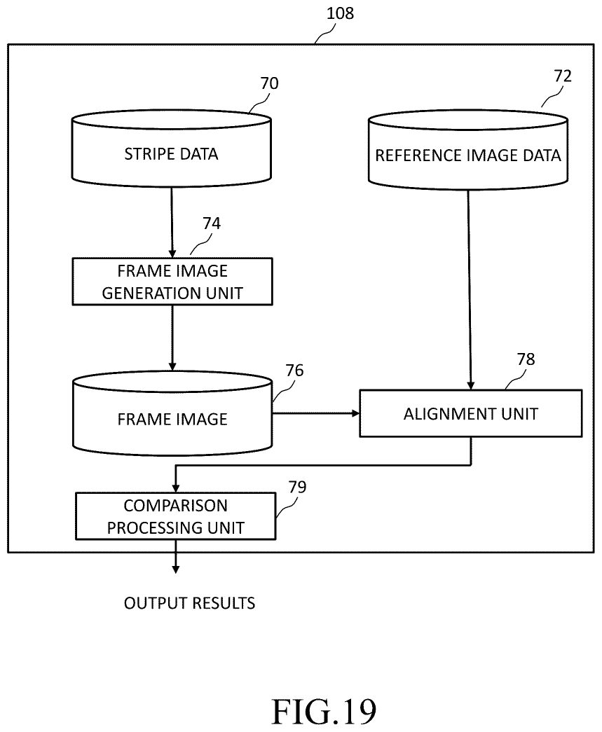

FIG. 19 is an example of an internal configuration of a comparison circuit according to the first embodiment. As shown in FIG. 19, in the comparison circuit 108, there are disposed storage devices 70, 72, and 76 such as magnetic disk drives, a frame image generation unit 74, an alignment unit 78, and a comparison processing unit 79. Each of the “units” such as the frame image generation unit 74, the alignment unit 78, and the comparison processing unit 79 includes processing circuitry. The processing circuitry includes, for example, an electric circuit, a computer, a processor, a circuit board, a quantum circuit, semiconductor device, or the like. Furthermore, common processing circuitry (the same processing circuitry), or different processing circuitry (separate processing circuitry) may be used for each of the “ . . . units”. Input data needed in the frame image generation unit 74, the alignment unit 78, and the comparison processing unit 79, and calculated (operated) results are stored in a memory (not shown) in the comparison circuit 108 or in the memory 111 each time.

Stripe data (stripe region image) input to the comparison circuit 108 is stored in the storage device 70. Reference image data input to the comparison circuit 108 is stored in the storage device 72.

In the comparison step (S140), the comparison circuit 108 (example of a comparison unit) compares an optical image formed by optical image data output from the imaging sensor 105 with a reference image. Specifically, it operates as described below.

In the comparison circuit 108, first, the frame image generation unit 74 generates a plurality of frame images 31 by dividing the stripe region image (optical image) by a predetermined width. Specifically, as shown in FIG. 2, a stripe region image is divided into frame images of a plurality of rectangular frame regions 30. For example, it is divided into the size of 512×512 pixels. Data of each frame region 30 is stored in the storage device 76.

Next, the alignment unit 78 reads, for each frame region 30, a corresponding frame image 31 and a corresponding reference image from the storage devices 72 and 76, and performs alignment (position adjustment) of the frame image 31 and the corresponding reference image based on a predetermined algorithm. For example, the alignment is performed according to the least-square method.

The comparison processing unit 79 (another example of the comparison unit) compares the frame image 31 with the reference image corresponding to the frame image 31 concerned. For example, comparing is performed for each pixel. Here, the comparison processing unit 79 compares, for each pixel, both the images based on predetermined determination conditions so as to determine whether there is a defect, such as a shape defect, or not. For example, based on predetermined algorithm as the determination conditions, both the images are compared with each other for each pixel to determine whether there is a defect or not. For example, for each pixel, a difference value between pixel values of the optical image and the reference image is calculated, and it is determined there is a defect when the difference value is larger than a threshold Th. Then, the comparison result is output to, for example, the magnetic disk drive 109, the magnetic tape drive 115, the flexible disk drive (FD) 116, the CRT 117, or the pattern monitor 118, or alternatively, output from the printer 119.

Although the case of performing the die-to-database inspection is described in the above example, the die-to-die inspection may also be used. In that case, with respect to frame regions of dies 1 and 2 for the die-to-die inspection in a plurality of frame regions 30, the comparison circuit 108 uses a frame image (optical image) of the die 2, as a reference (reference image). First, for each frame region 30 for which the die-to-die inspection is performed, the alignment unit 78 reads the frame image 31 of the die 1 and a corresponding frame image of the die 2 from the storage device 76, and performs alignment between the frame image 31 of the die 1 and the frame image of the die 2 based on a predetermined algorithm. For example, the alignment is performed using the least-square method. Then, for each frame region 30 for which the die-to-die inspection is performed, the comparison processing unit 79 (comparison unit) compares, for each pixel, the frame image 31 of the die 1 with the corresponding frame image of the die 2.

In the determination step (S142), the control computer 110 determines whether scanning and inspection for all the inspection stripes 20 have been completed. If scanning and inspection have not been completed for all the inspection stripes 20, it returns to the height position deviation amount distribution calculation step (S110), and repeats each step from the height position deviation amount distribution calculation step (S110) to the determination step (S142) while changing a target inspection stripe 20 in order until all the inspection stripes 20 have been scanned and inspected. When scanning and inspection for all the inspection stripes 20 are completed, the inspection processing operation is ended.

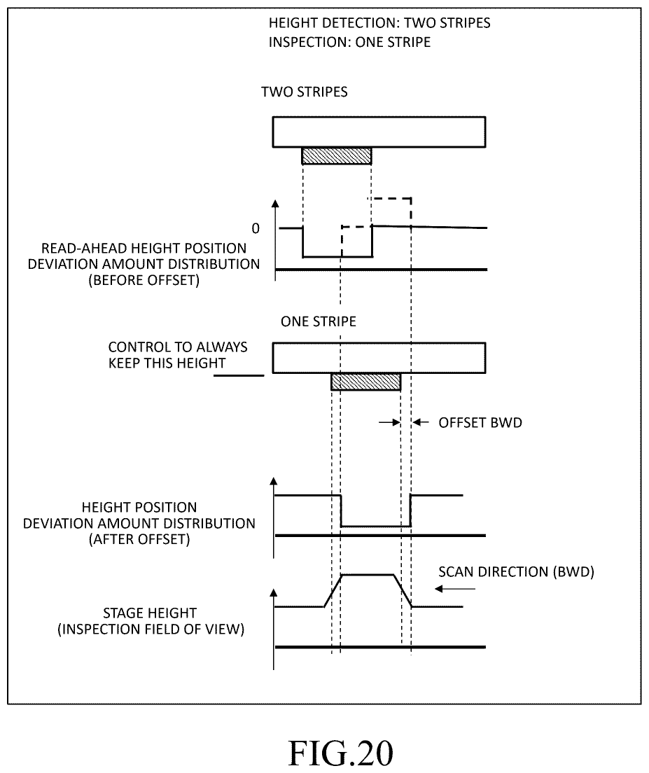

FIG. 20 is an illustration showing an example of a height distribution of the XYθ table (stage) at the first (n=1) inspection stripe, and an example of a height position deviation distribution at the second (n=2) inspection stripe according to the first embodiment. In the case of scanning the first (n=1) inspection stripe 20 with an inspection light, as described above, the height position of the XYθ table 102 (stage) is focus-controlled in accordance with the already acquired height position deviation amount distribution of the first (n=1) inspection stripe 20 deviated from the focus height position. However, as described above, if changing the height position of the XYθ table 102 (stage) is started when approaching the actual pattern end, blurring occurs due to an operation delay of the stage. Therefore, the offset processing unit 58 generates a height position deviation amount distribution in which the position of height change by a pattern is offset to the near side in the scanning direction by an acquired offset amount. FIG. 20 shows the case where the scanning direction over the first (n=1) inspection stripe 20 with the inspection light 14 is BWD. Therefore, in the height position deviation distribution of FIG. 20, the position of the pattern end is offset to the right by the offset amount for BWD. When scanning the first (n=1) inspection stripe 20 with the inspection light 14, simultaneously, scanning the second (n=2) inspection stripe 20 with the measuring light 16 is performed. In FIG. 20, the height position deviation distribution of the second (n=2) inspection stripe 20 is shown by the solid line. A different portion in the height position deviation distribution, based on a focus signal, of the second (n=2) inspection stripe 20 before differentiating with an actual height position of the XYθ table 102 (stage) in scanning the first (n=1) inspection stripe 20 with the inspection light 14 is shown by the dotted line.

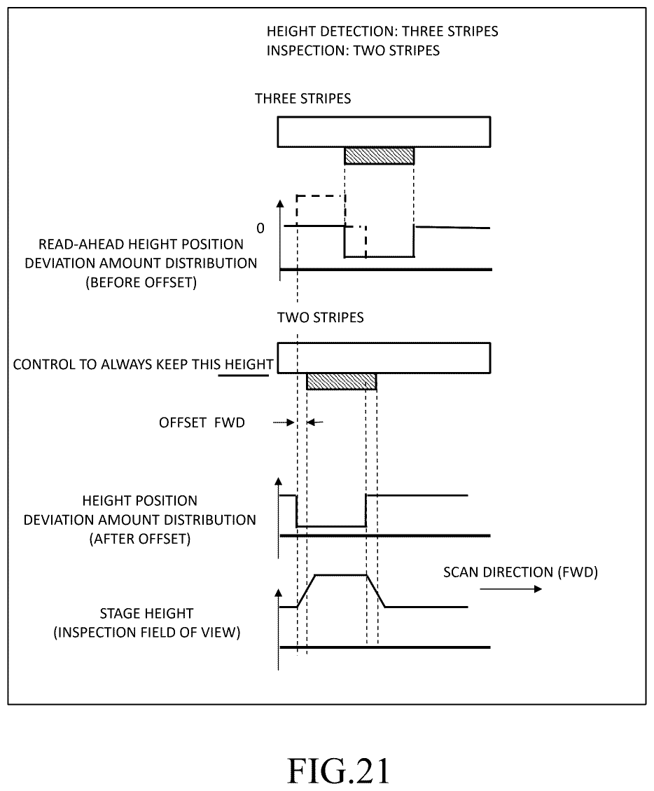

FIG. 21 is an illustration showing an example of a height distribution of the XYθ table (stage) at the second (n=2) inspection stripe, and an example of a height position deviation distribution at the third (n=3) inspection stripe according to the first embodiment. In the case of scanning the second (n=2) inspection stripe 20 with an inspection light, as described above, the height position of the XYθ table 102 (stage) is focus-controlled in accordance with the already acquired height position deviation amount distribution of the second (n=2) inspection stripe 20 deviated from the focus height position. The offset processing unit 58 generates a height position deviation amount distribution in which the position of height change by a pattern is offset to the near side in the scanning direction by an acquired offset amount. FIG. 21 shows the case where the scanning direction over the second (n=2) inspection stripe 20 with the inspection light 14 is FWD. Therefore, in the height position deviation distribution of FIG. 21, the position of the pattern end is offset to the left by the offset amount for FWD. When scanning the second (n=2) inspection stripe 20 with the inspection light 14, simultaneously, scanning the third (n=3) inspection stripe 20 with the measuring light 16 is performed. In FIG. 21, the height position deviation distribution of the third (n=3) inspection stripe 20 is shown by the solid line. A different portion in the height position deviation distribution, based on a focus signal, of the third (n=3) inspection stripe 20 before differentiating with an actual height position of the XYθ table 102 (stage) in scanning the second (n=2) inspection stripe 20 with the inspection light 14 is shown by the dotted line.

As described above, according to the first embodiment, since the height position deviation distribution of the k-th (n=k) inspection stripe 20 can be previously acquired before starting scanning the k-th (n=k) inspection stripe 20 with the inspection light 14, it is possible to adjust the stage drive at the time of scanning the k-th (n=k) inspection stripe 20. Therefore, a follow-up delay of the stage movement in focusing the inspection field of view can be prevented or reduced. As a result, a defect misidentification, or a defect detection omission can be prevented or reduced.

Embodiments have been explained referring to specific examples described above. However, the present invention is not limited to these specific examples.

While the apparatus configuration, control method, and the like not directly necessary for explaining the present invention are not described, some or all of them can be appropriately selected and used on a case-by-case basis when needed. For example, although description of the configuration of the control unit for controlling the inspection apparatus 100 is omitted, it should be understood that some or all of the configuration of the control unit can be selected and used appropriately when necessary.

Furthermore, any pattern inspection apparatus and pattern inspection method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern inspection apparatus comprising:
a light source configured to emit a first light;
a stage configured to be movable and to mount thereon a target object on which a pattern is formed;
a slit plate, in which an opening is formed, configured to restrict a passage of a measuring light which is a portion of the first light emitted from the light source and is for measuring a deviation amount of the target object from a focus height;
an illumination optical system configured to irradiate the target object with the measuring light having passed through the slit plate;
a stage control circuit configured to control a movement of the stage such that each stripe region of a plurality of stripe regions obtained by dividing an inspection region of the target object by a predetermined width is scanned with an inspection light being another portion of the first light emitted from the light source;
a sensor configured to receive a pattern image of the target object formed by a light, being one of a light transmitted through the target object and a light reflected from the target object, due to scanning with the inspection light;
a comparison circuit configured to compare the pattern image received by the sensor with a predetermined reference image; and
a height adjustment mechanism configured to adjust a height position of a pattern forming surface of the target object to a focus height position of the inspection light by using a height position deviation amount distribution which is acquired based on applying the measuring light to the target object and indicates a deviation amount of the pattern forming surface of the target object deviated from the focus height position, wherein
in a case of scanning a k-th (k being an integer of at least 1) stripe region with the inspection light, an irradiation position of the inspection light on the target object and an irradiation position of the measuring light on the target object are set such that a (k+m)th (m being an integer of at least 1) stripe region is scanned with the measuring light.

2. The apparatus according to claim 1, further comprising:
a height position deviation amount measuring mechanism configured to receive, for each of the plurality of stripe regions, a second light reflected from the target object due to scanning a stripe region concerned with the measuring light, and measures, based on the second light received, a deviation amount of the height position of the pattern forming surface of the stripe region concerned deviated from a focus height position of the measuring light; and
a height position deviation amount distribution generating circuit configured to generate, for each of the plurality of stripe regions, a height position deviation amount distribution of the pattern forming surface of the stripe region concerned, deviated from the focus height position of the measuring light.

3. The apparatus according to claim 2, wherein, in a case of generating the height position deviation amount distribution, the height position deviation amount distribution generating circuit offsets, in a direction parallel to a scanning direction of scanning a stripe region, a time position of the scanning at which a height position changes.

4. The apparatus according to claim 2, wherein, the height position deviation amount measuring mechanism includes a confocal sensor which measures a first light amount of the second light at a front focus position and a second light amount of the second light at a back focus position, and outputs, using the first light amount and the second light amount, a parameter capable of calculating the deviation amount of the height position.

5. The apparatus according to claim 1, wherein the illumination optical system further irradiates the target object with the inspection light.

6. The apparatus according to claim 4, wherein the height position deviation amount distribution generating circuit includes a difference calculation circuit which calculates a difference distribution obtained by subtracting a stage height position deviation distribution deviated from a focus height position in the k-th stripe region scanned with the inspection light simultaneously with scanning with the measuring light, from a height position deviation distribution, based on the parameter, of the (k+m)th stripe region scanned with the measuring light, as a height position deviation distribution of the (k+m)th stripe region scanned with the measuring light.

7. The apparatus according to claim 6, wherein the height position deviation amount distribution generating circuit further includes an offset processing circuit which wholly offsets, in a direction parallel to a scanning direction of scanning a stripe region, a position of a scanning direction at which a height position changes, with respect to the height position deviation amount distribution in the (k+m)th stripe region acquired by the difference distribution.

8. The apparatus according to claim 7, further comprising:
an offset calculation circuit configured to calculate an offset amount based on an operation delay time of the stage, wherein
the offset calculation circuit offsets, using the offset amount calculated, the position of the scanning direction at which the height position changes.

9. The apparatus according to claim 1, wherein
the illumination optical system includes an objective lens, and
a center position between an inspection field of view in a case of scanning the k-th (k being an integer of at least 1) stripe region with the inspection light and an image of the measuring light in a case of scanning the (k+m)th (m being an integer of at least 1) stripe region is arranged at a center of an objective lens field of view of the objective lens.

10. A pattern inspection method comprising:
restricting, using a slit plate in which an opening is formed, a passage of a measuring light which is a portion of a first light emitted from a light source and is for measuring a deviation amount of a target object from a focus height;
irradiating, using an illumination optical system, the target object, on which a pattern is formed and which is placed on a stage, with the measuring light having passed through the slit plate;
scanning each stripe region of a plurality of stripe regions, obtained by dividing an inspection region of the target object by a predetermined width, with an inspection light being another portion of the first light emitted from the light source;
receiving, by a sensor, a pattern image of the target object formed by a light, being one of a light transmitted through the target object and a light reflected from the target object, due to scanning with the inspection light;
comparing the pattern image received by the sensor with a predetermined reference image; and 5 adjusting a height position of a pattern forming surface of the target object to a focus height position of the inspection light by using a height position deviation amount distribution which is acquired based on applying the measuring light to the target object and indicates a deviation amount of 10 the pattern forming surface of the target object deviated from the focus height position, wherein
in a case of scanning a k-th (k being an integer of at least 1) stripe region with the inspection light, an irradiation position of the inspection light on the target object and an irradiation position of the measuring light on the target object are set such that a (k+m)th (m being an integer of at least 1) stripe region is scanned with the measuring light.
